(19) United States
(12) Patent Application Publication
(10) Pub. No.: US 2022/0301483 A1
(43) Pub. Date: Sep. 22, 2022

(54) GOA CIRCUIT AND DISPLAY PANEL

(71) Applicants: Jian TAO, Wuhan, Hubei (CN); Fei TENG, Wuhan, Hubei (CN); Junhui GUO, Wuhan, Hubei (CN)

(72) Inventors: Jian TAO, Wuhan, Hubei (CN); Fei TENG, Wuhan, Hubei (CN); Junhui GUO, Wuhan, Hubei (CN)

(73) Assignees: WUHAN CHINA STAR OPTOELECTRONICS TECHNOLOGY CO., LTD., Wuhan, Hubei (CN); WUHAN CHINA STAR OPTOELECTRONICS TECHNOLOGY CO., LTD., Wuhan, Hubei (CN)

(21) Appl. No.: 16/979,796

(22) PCT Filed: Jul. 29, 2020
(86) PCT No.: PCT/CN2020/105540

§ 371 Date: Sep. 10, 2020

(30) Foreign Application Priority Data
Jul. 9, 2020 (CN) 202010656941.6

(51) Int. Cl. G09G 3/20

(52) U.S. Cl. CPC G09G 3/2092; G09G 2310/0291; G09G 2310/0267; G09G 2310/061

(57) ABSTRACT

A GOA circuit and a display panel are provided. Each stage of GOA units is equivalent to multiple cascaded GOA units in the conventional GOA circuit and could orderly output multiple scan signals according to their timing such that each stage of GOA units could control multiple rows of the pixel units of the display panel to display an image. In this way, the number of the TFTs in the GOA circuit could be reduced, the layout and space of the GOA circuit could also be reduced such that the size of the side frame could be reduced and the narrow side frame demands could be met.

### FIELD OF THE INVENTION

The present invention relates to a display technique, and more particularly, to a GOA circuit and a display panel.

### BACKGROUND OF THE INVENTION

The gate driver on array (GOA) technique represents a technique integrating the gate drivers on the glass substrate for the scan of the display panel. The GOA technique could reduce the bonding processes for the external ICs and thus could reduce the cost and better fit the display devices having no side frames or narrow side frames.

The GOA circuit may comprise cascaded GOA units and is mainly integrated on the glass substrate and thus needs to occupy the areas at two sides. However, the demands of narrow side frame or no side frame becomes higher.

### SUMMARY

Conventionally, each of the GOA units in the GOA circuit is used to output a gate driving signal to control a row of pixel units to display an image. Because the number of the thin film transistors (TFTs) is still large, it is difficult to reduce the size of the side frame of the display panel.

In order to solve the above-mentioned issue, one objective of an embodiment of the present invention is to provide a gate driver on array (GOA) circuit. The GOA circuit comprises a plurality of cascaded GOA units. Each of the GOA unit comprises: a forward/backward scan module; a first latch module; a second latch module; and a buffer output module. The second latch module comprises a plurality of NAND gate circuits connected in parallel. The buffer output module comprises a plurality of buffer output circuits connected in parallel, wherein the plurality of NAND gate circuits and the plurality of buffer output circuits have one-to-one correspondence. The forward/backward scan module, the first latch module, the second latch module, and the buffer output module are connected in series. Each of the buffer output circuits outputs a corresponding gate scan signal such that the GOA units output a plurality of the gate scan signals.

In some embodiments, the forward/backward scan module comprises: a 1^{st} TFT; a 2^{nd} TFT; a 3^{rd} TFT and a 4^{th} TFT; wherein the 1^{st} TFT and the 4^{th} TFT are N-type TFTs and the 2^{nd} TFT and the 3^{rd} TFT are P-type TFTs. A gate of the 1^{st} TFT and a gate of the 3^{rd} TFT receive a forward scan signal; a gate of the 2^{nd} TFT and a gate of the 4^{th} TFT receive a backward scan signal; a source of the 1^{st} TFT and a source of the 2^{nd} TFT receive a previous-stage stage signal (ST(n−1)) of a previous-stage GOA unit. A source of the 3^{rd} TFT and a source of the 4^{th} TFT receive a next-stage stage signal (ST(n+1)) of a next-stage GOA unit. Drains of the 1^{st} TFT, the 2^{nd} TFT, the 3^{rd} TFT, and the 4^{th} TFT are all electrically connected to a second node.

In some embodiments, the first latch module comprises: a first inverter, comprising a 9^{th} TFT and a 10^{th} TFT; and a selection inverter, comprising a 5^{th} TFT, a 6^{th} TFT, a 7^{th} TFT, a 8^{th} TFT, a 11^{th} TFT, a 12^{th} TFT, a 13^{th} TFT, and a 14^{th} TFT. The first inverter and the selection inverter are connected in series. The 10^{th} TFT, the 11^{th} TFT, the 12^{th} TFT, the 13^{th} TFT, and the 14^{th} TFT are N-type TFTs; and the 5^{th} TFT, the 6^{th} TFT, and the 7^{th} TFT, the 8^{th} TFT, and the 9^{th} TFT are P-type TFTs. A gate of the 9^{th} TFT and a gate of the 10^{th} TFT receive a n^{th} clock signal (CK(n)). A source of the 9^{th} TFT receives a constant high voltage level, a source of the 10^{th} TFT receives a constant low voltage level. A drain of the 9^{th} TFT and a drain of the 10^{th} TFT output an inverted n^{th} clock signal (CK(n)′) of the n^{th} clock signal (CK(n)). A gate of the 7^{th} TFT and a gate of the 11^{th} TFT receive the inverted n^{th} clock signal (CK(n)′). A gate of the 5^{th} TFT is electrically connected to the second node; a gate of the 6^{th} TFT and a gate of the 12^{th} TFT receive the n^{th} clock signal (CK(n)); a gate of the 8^{th} TFT and a gate of the 13^{th} TFT receive a current-stage stage signal (ST(n)) of a current-stage GOA unit. A gate of 14^{th} TFT is electrically connected to the second node. Drains of the 5^{th} TFT, the 6^{th} TFT, the 7^{th} TFT and the 8^{th} TFT are electrically connected to each other; drains of the 11^{th} TFT, the 12^{th} TFT, the 13^{th} TFT, and the 14^{th} TFT are electrically connected to each other. Drains of the 7^{th} TFT, the 8^{th} TFT, the 12^{th} TFT, and the 14^{th} TFT are electrically connected to a first node.

In some embodiments, the GOA circuit further comprises a reset module. The reset module comprises a 15^{th} TFT, having a gate receiving a reset signal (Reset), a source receiving the constant high voltage level, and a drain electrically connected to the first node.

In some embodiments, the second latch module further comprises a plurality of second inverters respectively connected in series with the NAND gate circuits. The second inverter comprises a 16^{th} TFT and a 17^{th} TFT, the 16^{th} TFT is a P-type TFT and the 17^{th} TFT is an N-type TFT. A source of the 16^{th} TFT receives the constant high voltage level, a gate of the 16^{th} TFT and a gate of the 17^{th} TFT are electrically connected to the first node; a source of the 17^{th} TFT receives the constant low voltage level; drains of the 16^{th} TFT and the 17^{th} TFT output the current-stage stage signal (ST(n)).

In some embodiments, if one stage of the GOA units outputs a first scan signal (G(n)) and a second scan signal (G(n)′), the second latch module comprises a first NAND gate circuit and a second NAND gate circuit; the buffer output module comprises a first buffer output circuit and a second buffer output circuit. The first NAND gate circuit comprises 19^{th} TFT, a 20^{th} TFT, a 21^{st} TFT, and a 22^{nd} TFT. The 19^{th} TFT and the 20^{th} TFT are P-type TFTs. The 21^{st} TFT and the 22^{nd} TFT are P-type TFTs. The second NAND gate circuit comprises a 19^{th} symmetric TFT, a 20^{th} symmetric TFT, and a 21^{st} symmetric TFT. The 19^{th} symmetric TFT and the 20^{th} symmetric TFT are P-type TFTs. The 21^{st} symmetric TFT is an N-type TFT. Gates of the 19^{th} TFT, the 22^{nd} TFT, and the 19^{th} symmetric TFT receive the current-stage stage signal (ST(n)), gates of the 20^{th} TFT and the 21^{st} TFT receive a (n+1)th clock signal (CK(n+1)); sources of the 19^{th} TFT and the 20^{th} TFT receive the constant high voltage level; drains of the 19^{th} TFT and the 20^{th} TFT are electrically connected to a source of the 21^{st} TFT; a drain of the 21^{st} TFT is electrically connected to drains of the 22^{nd} TFT and the 21^{st} symmetric TFT; sources of the 19^{th} TFT, the 20^{th} symmetric TFT and the 22^{nd} TFT receive the constant low voltage level; drains of the 19^{th} symmetric TFT and the 20^{th} symmetric TFT are electrically connected to a source of the 21^{st} symmetric TFT; and gates of the 20^{th} symmetric TFT and the 21^{st} symmetric TFT receive a (n+2)th clock signal (CK(n+2)). The first buffer output circuit and the second buffer output circuit respectively comprises an odd number of third inverters connected in series, the first buffer output circuit outputs the first scan signal (G(n)) and the second buffer output circuit outputs the second scan signal (G(n)′).

In some embodiments, the GOA circuit has four clock signals: a 1^{st} clock signal (CK1), a 2^{nd} clock signal (CK2), a 3^{rd} clock signal (CK3) and a 4^{th} clock signal (CK4); wherein when the n^{th} clock signal (CK(n)) is the 3^{rd} clock signal (CK3), the (n+1)th clock signal (CK(n+1)) is the 4^{th} clock signal (CK4) and the (n+2)th clock signal (CK(n+2)) is the 1^{st} clock signal (CK1); and when the n^{th} clock signal (CK(n)) is the 4^{th} clock signal (CK4), the (n+1)th clock signal (CK(n+1)) is the 1^{st} clock signal (CK1) and the (n+2)th clock signal (CK(n+2)) is the 2^{nd} clock signal (CK2).

In some embodiments, the n^{th} clock signal (CK(n)) is the 1^{st} clock signal (CK1), the operation of the GOA circuit comprises an initial stage (t0), an input stage (t1), a first output stage (t2), a first pull-down and a second output stage (t3), a second pull-down stage (t4), and a maintaining stage (t5). In the initial stage (t0), the reset signal (Reset) corresponds to a low voltage level such that the first node corresponds to a low voltage level and the current-stage stage signal (ST(n)) corresponds to a high voltage level to make the buffer output module outputs a low voltage level. In the input stage (t1), the previous-stage stage signal (ST(n−1)) corresponds to a high voltage level such that the second node corresponds to a high voltage level and the 5^{th} TFT is turned off and the 14^{th} TFT is turned on; the 1^{st} clock signal (CK1) corresponds to a high voltage level such that the 6^{th} TFT is turned off and the 12^{th} TFT is turned on; the inverted n^{th} clock signal (CK(n)′) corresponds to a low voltage level such that the 11^{th} TFT is turned off; the 12^{th} TFT and the 14^{th} TFT are turned on such that the first node corresponds to a low voltage level to make the current-stage stage signal (ST(n)) a high voltage level. In the first output stage (t2), the 2^{nd} clock signal (CK2) corresponds to a high voltage level and the current-stage stage signal (ST(n)) corresponds to a high voltage level such that the first NAND gate circuit outputs a low voltage level to make the first buffer output circuit outputs the first scan signal (G(n)) having a high voltage level. In the first pull-down and a second output stage (t3), the 2^{nd} clock signal (CK2) corresponds to a low voltage level, the 3^{rd} clock signal (CK3) corresponds to a high voltage level, and the current-stage stage signal (ST(n)) corresponds to a high voltage level such that the first NAND circuit outputs a high voltage level to make the first buffer output circuit output the first scan signal (G(n)) having a low voltage level such that the second buffer output circuit outputs the second scan signal (G(n)′) having a high voltage level. In the second pull-down stage (t4), the 3^{rd} clock signal (CK3) corresponds to a low voltage level and the current-stage stage signal (ST(n)) corresponds to a high voltage level such that the second NAND circuit outputs a high voltage level to make the second buffer output circuit output the second scan signal (G(n)′) having a low voltage level. In the maintaining stage (t5), the previous-stage stage signal (ST(n−1)) corresponds to a low voltage level such that the second node corresponds to a low voltage level to turn on the 5^{th} TFT and turn off the 14^{th} TFT; the 1^{st} clock signal (CK1) corresponds to a high voltage level to turn off the 6^{th} TFT and turn on the 12^{th} TFT; the inverted n^{th} clock signal (CK(n)′) corresponds to a low voltage level to turn on the 7^{th} TFT and turn off the 11^{th} TFT; the 5^{th} TFT and the 7^{th} TFT are turned on such that the first node corresponds to a high voltage level to make the current-stage stage signal (ST(n)) a low voltage level and the first NAND gate circuit and the second NAND gate circuit both output a high voltage level and to further make the first buffer output circuit output the first scan signal (G(n)) having a low voltage level and the second buffer output circuit output the second scan signal (G(n)′) having a low voltage level.

In some embodiments, each of the NAND gate circuits in the second latch module respectively receives a corresponding clock signal and the corresponding clock signal is a continuous pulse signal.

One objective of an embodiment of the present invention is to provide a display panel. The display panel comprises a gate driver on array (GOA) circuit. The GOA circuit comprises a plurality of cascaded GOA units. Each of the GOA unit comprises: a forward/backward scan module; a first latch module; a second latch module; and a buffer output module. The second latch module comprises a plurality of NAND gate circuits connected in parallel. The buffer output module comprises a plurality of buffer output circuits connected in parallel, wherein the plurality of NAND gate circuits and the plurality of buffer output circuits have one-to-one correspondence. The forward/backward scan module, the first latch module, the second latch module, and the buffer output module are connected in series. Each of the buffer output circuits outputs a corresponding gate scan signal such that the GOA units output a plurality of the gate scan signals.

In some embodiments, the forward/backward scan module comprises: a 1^{st} TFT; a 2^{nd} TFT; a 3^{rd} TFT and a 4^{th} TFT; wherein the 1^{st} TFT and the 4^{th} TFT are N-type TFTs and the 2^{nd} TFT and the 3^{rd} TFT are P-type TFTs. A gate of the 1^{st} TFT and a gate of the 3^{rd} TFT receive a forward scan signal; a gate of the 2^{nd} TFT and a gate of the 4^{th} TFT receive a backward scan signal; a source of the 1^{st} TFT and a source of the 2^{nd} TFT receive a previous-stage stage signal (ST(n−1)) of a previous-stage GOA unit. A source of the 3^{rd} TFT and a source of the 4^{th} TFT receive a next-stage stage signal (ST(n+1)) of a next-stage GOA unit. Drains of the 1^{st} TFT, the 2^{nd} TFT, the 3^{rd} TFT, and the 4^{th} TFT are all electrically connected to a second node.

In some embodiments, the first latch module comprises: a first inverter, comprising a 9^{th} TFT and a 10^{th} TFT; and a selection inverter, comprising a 5^{th} TFT, a 6^{th} TFT, a 7^{th} TFT, a 8^{th} TFT, a 11^{th} TFT, a 12^{th} TFT, a 13^{th} TFT, and a 14^{th} TFT. The first inverter and the selection inverter are connected in series. The 10^{th} TFT, the 11^{th} TFT, the 12^{th} TFT, the 13^{th} TFT, and the 14^{th} TFT are N-type TFTs; and the 5^{th} TFT, the 6^{th} TFT, and the 7^{th} TFT, the 8^{th} TFT, and the 9^{th} TFT are P-type TFTs. A gate of the 9^{th} TFT and a gate of the 10^{th} TFT receive a n^{th} clock signal (CK(n)). A source of the 9^{th} TFT receives a constant high voltage level, a source of the 10^{th} TFT receives a constant low voltage level. A drain of the 9^{th} TFT and a drain of the 10^{th} TFT output an inverted n^{th} clock signal (CK(n)′) of the n^{th} clock signal (CK(n)). A gate of the 7^{th} TFT and a gate of the 11^{th} TFT receive the inverted n^{th} clock signal (CK(n)′). A gate of the 5^{th} TFT is electrically connected to the second node; a gate of the 6^{th} TFT and a gate of the 12^{th} TFT receive the n^{th} clock signal (CK(n)); a gate of the 8^{th} TFT and a gate of the 13^{th} TFT receive a current-stage stage signal (ST(n)) of a current-stage GOA unit. A gate of 14^{th} TFT is electrically connected to the second node. Drains of the 5^{th} TFT, the 6^{th} TFT, the 7^{th} TFT and the 8^{th} TFT are electrically connected to each other; drains of the 11^{th} TFT, the 12^{th} TFT, the 13^{th} TFT, and the 14^{th} TFT are electrically connected to each other. Drains of the 7^{th} TFT, the 8^{th} TFT, the 12^{th} TFT, and the 14^{th} TFT are electrically connected to a first node.

In some embodiments, the GOA circuit further comprises a reset module. The reset module comprises a 15^{th} TFT, having a gate receiving a reset signal (Reset), a source receiving the constant high voltage level, and a drain electrically connected to the first node.

In some embodiments, the second latch module further comprises a plurality of second inverters respectively connected in series with the NAND gate circuits. The second inverter comprises a 16^{th} TFT and a 17^{th} TFT, the 16^{th} TFT is a P-type TFT and the 17^{th} TFT is an N-type TFT. A source of the 16^{th} TFT receives the constant high voltage level, a gate of the 16^{th} TFT and a gate of the 17^{th} TFT are electrically connected to the first node; a source of the 17^{th} TFT receives the constant low voltage level; drains of the 16^{th} TFT and the 17^{th} TFT output the current-stage stage signal (ST(n)).

In some embodiments, if one stage of the GOA units outputs a first scan signal (G(n)) and a second scan signal (G(n)′), the second latch module comprises a first NAND gate circuit and a second NAND gate circuit; the buffer output module comprises a first buffer output circuit and a second buffer output circuit. The first NAND gate circuit comprises 19^{th} TFT, a 20^{th} TFT, a 21^{st} TFT, and a 22^{nd} TFT. The 19^{th} TFT and the 20^{th} TFT are P-type TFTs. The 21^{st} TFT and the 22^{nd} TFT are P-type TFTs. The second NAND gate circuit comprises a 19^{th} symmetric TFT, a 20^{th} symmetric TFT, and a 21^{st} symmetric TFT. The 19^{th} symmetric TFT and the 20^{th} symmetric TFT are P-type TFTs. The 21^{st} symmetric TFT is an N-type TFT. Gates of the 19^{th} TFT, the 22^{nd} TFT, and the 19^{th} symmetric TFT receive the current-stage stage signal (ST(n)), gates of the 20^{th} TFT and the 21^{st} TFT receive a (n+1)th clock signal (CK(n+1)); sources of the 19^{th} TFT and the 20^{th} TFT receive the constant high voltage level; drains of the 19^{th} TFT and the 20^{th} TFT are electrically connected to a source of the 21^{st} TFT; a drain of the 21^{st} TFT is electrically connected to drains of the 22^{nd} TFT and the 21^{st} symmetric TFT; sources of the 19^{th} TFT, the 20^{th} symmetric TFT and the 22^{nd} TFT receive the constant low voltage level; drains of the 19^{th} symmetric TFT and the 20^{th} symmetric TFT are electrically connected to a source of the 21^{st} symmetric TFT; and gates of the 20^{th} symmetric TFT and the 21^{st} symmetric TFT receive a (n+2)th clock signal (CK(n+2)). The first buffer output circuit and the second buffer output circuit respectively comprise an odd number of third inverters connected in series, the first buffer output circuit outputs the first scan signal (G(n)) and the second buffer output circuit outputs the second scan signal (G(n)′).

In some embodiments, the GOA circuit has four clock signals: a 1^{st} clock signal (CK1), a 2^{nd} clock signal (CK2), a 3^{rd} clock signal (CK3) and a 4^{th} clock signal (CK4); wherein when the n^{th} clock signal (CK(n)) is the 3^{rd} clock signal (CK3), the (n+1)th clock signal (CK(n+1)) is the 4^{th} clock signal (CK4) and the (n+2)th clock signal (CK(n+2)) is the 1^{st} clock signal (CK1); and when the n^{th} clock signal (CK(n)) is the 4^{th} clock signal (CK4), the (n+1)th clock signal (CK(n+1)) is the 1^{st} clock signal (CK1) and the (n+2)th clock signal (CK(n+2)) is the 2^{nd} clock signal (CK2).

In some embodiments, the n^{th} clock signal (CK(n)) is the 1^{st} clock signal (CK1), the operation of the GOA circuit comprises an initial stage (t0), an input stage (t1), a first output stage (t2), a first pull-down and a second output stage (t3), a second pull-down stage (t4), and a maintaining stage (t5). In the initial stage (t0), the reset signal (Reset) corresponds to a low voltage level such that the first node corresponds to a low voltage level and the current-stage stage signal (ST(n)) corresponds to a high voltage level to make the buffer output module outputs a low voltage level. In the input stage (t1), the previous-stage stage signal (ST(n−1)) corresponds to a high voltage level such that the second node corresponds to a high voltage level and the 5^{th} TFT is turned off and the 14^{th} TFT is turned on; the 1^{st} clock signal (CK1) corresponds to a high voltage level such that the 6^{th} TFT is turned off and the 12^{th} TFT is turned on; the inverted n^{th} clock signal (CK(n)′) corresponds to a low voltage level such that the 11^{th} TFT is turned off; the 12^{th} TFT and the 14^{th} TFT are turned on such that the first node corresponds to a low voltage level to make the current-stage stage signal (ST(n)) a high voltage level. In the first output stage (t2), the 2^{nd} clock signal (CK2) corresponds to a high voltage level and the current-stage stage signal (ST(n)) corresponds to a high voltage level such that the first NAND gate circuit outputs a low voltage level to make the first buffer output circuit outputs the first scan signal (G(n)) having a high voltage level. In the first pull-down and a second output stage (t3), the 2^{nd} clock signal (CK2) corresponds to a low voltage level, the 3^{rd} clock signal (CK3) corresponds to a high voltage level, and the current-stage stage signal (ST(n)) corresponds to a high voltage level such that the first NAND circuit outputs a high voltage level to make the first buffer output circuit output the first scan signal (G(n)) having a low voltage level such that the second buffer output circuit outputs the second scan signal (G(n)′) having a high voltage level. In the second pull-down stage (t4), the 3^{rd} clock signal (CK3) corresponds to a low voltage level and the current-stage stage signal (ST(n)) corresponds to a high voltage level such that the second NAND circuit outputs a high voltage level to make the second buffer output circuit output the second scan signal (G(n)′) having a low voltage level. In the maintaining stage (t5), the previous-stage stage signal (ST(n−1)) corresponds to a low voltage level such that the second node corresponds to a low voltage level to turn on the 5^{th} TFT and turn off the 14^{th} TFT; the 1^{st} clock signal (CK1) corresponds to a high voltage level to turn off the 6^{th} TFT and turn on the 12^{th} TFT; the inverted n^{th} clock signal (CK(n)′) corresponds to a low voltage level to turn on the 7^{th} TFT and turn off the 11^{th} TFT; the 5^{th} TFT and the 7^{th} TFT are turned on such that the first node corresponds to a high voltage level to make the current-stage stage signal (ST(n)) a low voltage level and the first NAND gate circuit and the second NAND gate circuit both output a high voltage level and to further make the first buffer output circuit output the first scan signal (G(n)) having a low voltage level and the second buffer output circuit output the second scan signal (G(n)′) having a low voltage level.

In some embodiments, each of the NAND gate circuits in the second latch module respectively receives a corresponding clock signal and the corresponding clock signal is a continuous pulse signal.

In the GOA circuit and the display panel, the forward/backward scan module and the first latch module of each stage of GOA units become a common part. The second latch module following the first latch module comprises multiple NAND gate circuits connected in parallel. The buffer output module following the second latch module comprises a plurality of buffer output circuits connected in parallel. Here, the NAND gate circuits and the buffer output circuits are connected to each other and have one-to-one correspondence. Each buffer output circuit could output a scan signal such that each stage of the GOA units could output multiple scan signals. The GOA circuit could share a part of each stage of the GOA units and also optimize the timing of the GOA circuit and the connections within the stages of the GOA circuit. Each stage of GOA units is equivalent to multiple cascaded GOA units in the conventional GOA circuit and could orderly output multiple scan signals according to their timing such that each stage of GOA units could control multiple rows of the pixel units of the display panel to display an image. In this way, the number of the TFTs in the GOA circuit could be reduced, the layout and space of the GOA circuit could also be reduced such that the size of the side frame could be reduced and the narrow side frame demands could be met.

### BRIEF DESCRIPTION OF THE DRAWINGS

FIG. 1 is a simplified circuit diagram of a GOA circuit according to an embodiment of the present invention.

FIG. 2 is a detailed circuit diagram of a GOA circuit according to an embodiment of the present invention.

FIG. 3 is a timing diagram of a GOA circuit according to an embodiment of the present invention.

FIG. 4 is a functional block diagram of a display panel according to an embodiment of the present invention.

### DETAILED DESCRIPTION OF PREFERRED EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

In the following embodiments, in order to distinguish the other two electrodes other than the gate of a transistor, one electrode is called “source” and another electrode is called “drain.” Please note, the source and the drain are interchangeable because they are symmetric. According to the configurations in the figures, the middle end is designated as the gate, the signal input end is designated as the source and the signal output end is designated as the drain. Furthermore, the transistors in the following disclosure could be P-type transistors and/or N-type transistors. P-type transistors are turned on when a low voltage level is applied and turned off when a high voltage level is applied. In contrast, N-type transistors are turned on when a high voltage level is applied and turned off when a low voltage level is applied.

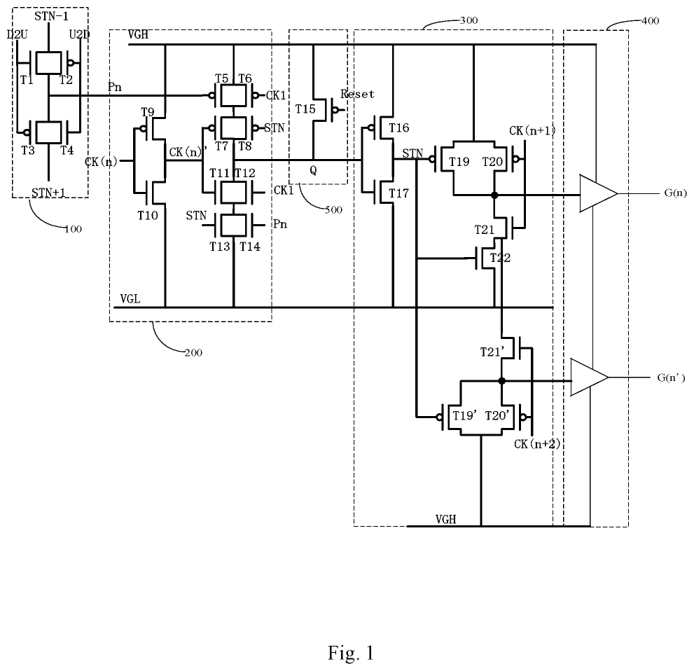

Please refer to FIG. 1. FIG. 1 is a simplified circuit diagram of a GOA circuit according to an embodiment of the present invention. The GOA circuit comprises a plurality of cascaded GOA units. Each stage of GOA units comprises a forward/backward scan module 100, a first latch module 200, a second latch module 300, and a buffer output module 400. The forward/backward scan module 100, the first latch module 200, the second latch module 300, and the buffer output module 400 are connected in series. The second latch module 300 comprises a plurality of NAND gate circuits connected in parallel. The buffer output module 400 comprises a plurality of buffer output circuits connected in parallel. The NAND gate circuits and the buffer output circuits are connected to each other and have one-to-one correspondence. Each buffer output circuit outputs the corresponding scan signal such that each stage of GOA units could output multiple scan signals.

In the GOA circuit, the forward/backward scan module 100 and the first latch module 200 of each stage of GOA units are a common part. The NAND gate circuits in the second latch module 300, following the first latch module 200, are one-to-one correspondingly connected to the buffer output circuits in the buffer output module 400 such that the buffer output circuits could output multiple scan signals. That is, each stage of GOA unit could output multiple scan signals. In contrast to the conventional GOA circuit, the GOA circuit of the present invention could enormously reduce the number of TFTs through sharing a part of modules/circuits without modifying basic structures. This reduces the occupied area of the GOA circuit and thus better meets the requirements of narrow side frame.

The forward/backward scan module 100 comprises a 1^{st} TFT T1, a 2^{nd} TFT T2, a 3^{rd} TFT T3 and a 4^{th} TFT T4. The 1^{st} TFT and the 4^{th} TFT are N-type TFTs and the 2^{nd} TFT and the 3^{rd} TFT are P-type TFTs. The gate of the 1^{st} TFT T1 and the gate of the 3^{rd} TFT T3 receive a forward scan signal U2D. The gate of the 2^{nd} TFT T2 and the gate of the 4^{th} TFT T4 receive a backward scan signal D2U. The source of the 1^{st} TFT T1 and the source of the 2^{nd} TFT T2 receive a previous-stage stage signal (ST(n−1)) of a previous-stage GOA unit. The source of the 3^{rd} TFT T3 and the source of the 4^{th} TFT T4 receive a next-stage stage signal (ST(n+1)) of a next-stage GOA unit. The drains of the 1^{st} TFT T1, the 2^{nd} TFT T2, the 3^{rd} TFT T3, and the 4^{th} TFT T4 are all electrically connected to a second node P.

The first latch module 200 comprises a first inverter 21 and a selection inverter 22. The first inverter and the selection inverter are connected in series. The first inverter 21 comprises a 9^{th} TFT T9 and a 10^{th} TFT T10. The selection inverter 22 comprises a 5^{th} TFT T5, a 6^{th} TFT T6, a 7^{th} TFT T7, a 8^{th} TFT T8, a 11^{th} TFT T11, a 12^{th} TFT T12, a 13^{th} TFT T13, and a 14^{th} TFT T14. The 10^{th} TFT T10, the 11^{th} TFT T11, the 12^{th} TFT T12, the 13^{th} TFT T13, and the 14^{th} TFT T14 are N-type TFTs. The 5^{th} TFT T5, the 6^{th} TFT T6, and the 7^{th} TFT T7, the 8^{th} TFT T8, and the 9^{th} TFT T9 are P-type TFTs.

The gate of the 9^{th} TFT and the gate of the 10^{th} TFT receive a n^{th} clock signal CK(n). The source of the 9^{th} TFT T9 receives a constant high voltage level VGH. The source of the 10^{th} TFT T10 receives a constant low voltage level VGL. The drain of the 9^{th} TFT T9 and a drain of the 10^{th} TFT T10 output an inverted n^{th} clock signal CK(n)′ of the n^{th} clock signal CK(n). The gate of the 7^{th} TFT T7 and the gate of the 11^{th} TFT T11 receive the inverted n^{th} clock signal CK(n)′. The gate of the 5^{th} TFT T5 is electrically connected to the second node P. The gate of the 6^{th} TFT T6 and the gate of the 12^{th} TFT T12 receive the n^{th} clock signal CK(n). The gate of the 8^{th} TFT T8 and the gate of the 13^{th} TFT T13 receive a current-stage stage signal ST(n) of a current-stage GOA unit. The gate of 14^{th} TFT T14 is electrically connected to the second node P. The drains of the 5^{th} TFT T5, the 6^{th} TFT T6, the 7^{th} TFT T7 and the 8^{th} TFT T8 are electrically connected to each other. The drains of the 11^{th} TFT T11, the 12^{th} TFT T12, the 13^{th} TFT T13, and the 14^{th} TFT T14 are electrically connected to each other. The drains of the 7^{th} TFT T7, the 8^{th} TFT T8, the 12^{th} TFT T12, and the 14^{th} TFT T14 are electrically connected to a first node Q.

As shown in FIG. 1, the GOA circuit further comprises a reset module 500. The reset module 500 comprises a 15^{th} TFT T15. The gate of the 15^{th} TFT T15 receives a reset signal Reset. The source of the 15^{th} TFT T15 receives the constant high voltage level VGH. The drain of the 15^{th} TFT T15 is electrically connected to the first node Q.

The second latch module 300 further comprises a plurality of second inverters 31 respectively connected in series with the NAND gate circuits. The second inverter 31 comprises a 16^{th} TFT T16 and a 17^{th} TFT T16. The 16^{th} TFT is a P-type TFT and the 17^{th} TFT T17 is an N-type TFT. The source of the 16^{th} TFT T16 receives the constant high voltage level. The gate of the 16^{th} TFT T16 and the gate of the 17^{th} TFT T17 are electrically connected to the first node Q. The source of the 17^{th} TFT T17 receives the constant low voltage level. The drains of the 16^{th} TFT T16 and the 17^{th} TFT T17 output the current-stage stage signal ST(n).

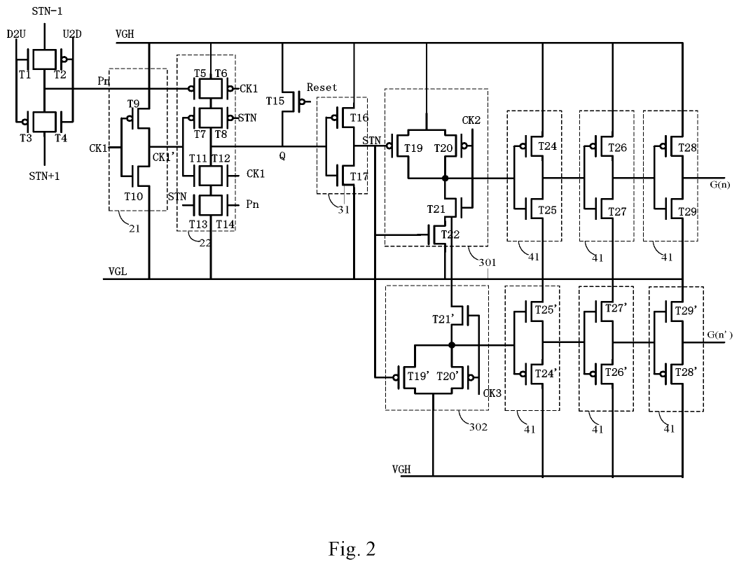

Please refer to FIG. 2. FIG. 2 is a detailed circuit diagram of a GOA circuit according to an embodiment of the present invention. As shown in FIG. 2, if any stage of the GOA units outputs the first scan signal G(n) and the second scan signal G(n)′, then the second latch module 300 comprises a first NAND gate circuit 301 and a second NAND gate circuit 302. The buffer output module 400 comprises a first buffer output circuit 401 and a second buffer output circuit 402.

The first NAND gate circuit 301 comprises a 19^{th} TFT T19, a 20^{th} TFT T20, a 21^{st} TFT T21, and a 22^{nd} TFT T22. The 19^{th} TFT T19 and the 20^{th} TFT T20 are P-type TFTs and the 21^{st} TFT T21 and the 22^{nd} TFT T22 are P-type TFTs. The second NAND gate circuit comprises a 19^{th} symmetric TFT T19′, a 20^{th} symmetric TFT T20′, and a 21^{st} symmetric TFT T21′. The 19^{th} symmetric TFT T19′ and the 20^{th} symmetric TFT T20′ are P-type TFTs. The 21^{st} symmetric TFT T21′ is an N-type TFT.

The gates of the 19^{th} TFT T19, the 22^{nd} TFT T22, and the 19^{th} symmetric TFT T19′ receive the current-stage stage signal ST(n). The gates of the 20^{th} TFT T20 and the 21^{st} TFT T21 receive a (n+1)th clock signal CK(n+1). The sources of the 19^{th} TFT T19 and the 20^{th} TFT T20 receive the constant high voltage level VGH. The drains of the 19^{th} TFT T19 and the 20^{th} TFT T20 are electrically connected to the source of the 21^{st} TFT T21. The drain of the 21^{st} TFT T21 is electrically connected to drains of the 22^{nd} TFT T22 and the 21^{st} symmetric TFT T21′. The sources of the 19^{th} TFT T19, the 20^{th} symmetric TFT T20′ and the 22^{nd} TFT T22 receive the constant low voltage level VGL. The drains of the 19^{th} symmetric TFT T19′ and the 20^{th} symmetric TFT T20′ are electrically connected to the source of the 21^{st} symmetric TFT T21′. The gates of the 20^{th} symmetric TFT T20′ and the 21^{st} symmetric TFT T21′ receive a (n+2)th clock signal CK(n+2).

The first buffer output circuit 401 and the second buffer output circuit 402 respectively comprises an odd number of third inverters 41 connected in series. The first buffer output circuit 401 outputs the first scan signal G(n) and the second buffer output circuit outputs the second scan signal G(n)′. For example, as shown in FIG. 2, the first buffer output circuit 401 and the second buffer output circuit 402 respectively comprise three third inverters 41 connected in series. Here, the 1^{st} third inverter 41 of the first buffer output circuit 401 is composed of a 24^{th} TFT T24 and a 25^{th} TFT T25. The 2^{nd} third inverter 41 of the first buffer output circuit 401 is composed of a 26^{th} TFT T26 and a 27^{th} TFT T27. The 3^{rd} third inverter 41 of the first buffer output circuit 401 is composed of a 28^{th} TFT T28 and a 29^{th} TFT T29. The 1^{st} third inverter 41 of the second buffer output circuit 402 is composed of a 24th symmetric TFT T24′ and a 25^{th} symmetric TFT T25′. The 2^{nd} third inverter 41 of the second buffer output circuit 402 is composed of a 26^{th} symmetric TFT T26′ and a 27^{th} symmetric TFT T27′. The 3^{rd} third inverter 41 of the second buffer output circuit 402 is composed of a 28^{th} symmetric TFT T28′ and a symmetric 29^{th} TFT T29′.

In some embodiments, the GOA circuit has four clock signals: a 1^{st} clock signal CK1, a 2^{nd} clock signal CK2, a 3^{rd} clock signal CK3 and a 4^{th} clock signal CK4. When the n^{th} clock signal CK(n) is the 3^{rd} clock signal CK3, the (n+1)th clock signal CK(n+1) is the 4^{th} clock signal CK4 and the (n+2)th clock signal CK(n+2) is the 1^{st} clock signal CK1. When the n^{th} clock signal CK(n) is the 4^{th} clock signal CK4, the (n+1)th clock signal CK(n+1) is the 1^{st} clock signal CK1 and the (n+2)th clock signal CK(n+2) is the 2^{nd} clock signal CK2.

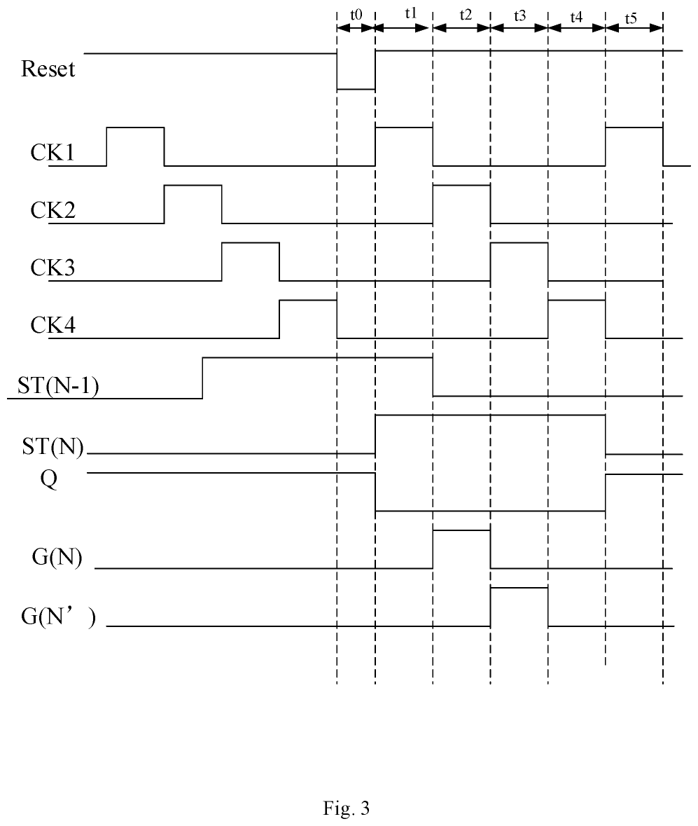

For example, if the n^{th} clock signal CK(n) is the 1^{st} clock signal CK1, then the (n+1)th clock signal CK(n+1) is the 2^{nd} clock signal CK2 and the (n+2)th clock signal CK(n+2) is the 3^{rd} clock signal CK3. Please refer to FIG. 2 and FIG. 3. FIG. 3 is a timing diagram of a GOA circuit according to an embodiment of the present invention. As shown in FIG. 2 and FIG. 3, the operation of the GOA circuit comprises an initial stage to, an input stage t1, a first output stage t2, a first pull-down and a second output stage t3, a second pull-down stage t4, and a maintaining stage t5.

In the initial stage t0, the reset signal Reset corresponds to a low voltage level such that the first node Q corresponds to a low voltage level and the current-stage stage signal ST(n) corresponds to a high voltage level to make the buffer output module outputs a low voltage level.

In the input stage t1, the previous-stage stage signal ST(n−1) corresponds to a high voltage level such that the second node P corresponds to a high voltage level and the 5^{th} TFT T5 is turned off and the 14^{th} TFT T14 is turned on. The 1^{st} clock signal CK1 corresponds to a high voltage level such that the 6^{th} TFT T6 is turned off and the 12^{th} TFT T12 is turned on. The inverted n^{th} clock signal CK(n)′ corresponds to a low voltage level such that the 11^{th} TFT T11 is turned off. The 12th TFT T12 and the 14^{th} TFT T14 are turned on such that the first node Q corresponds to a low voltage level to make the current-stage stage signal ST(n) a high voltage level.

In the first output stage t2, the 2^{nd} clock signal CK2 corresponds to a high voltage level and the current-stage stage signal ST(n) corresponds to a high voltage level such that the first NAND gate circuit outputs a low voltage level to make the first buffer output circuit outputs the first scan signal G(n) having a high voltage level.

In the first pull-down and a second output stage t3, the 2^{nd} clock signal CK2 corresponds to a low voltage level, the 3^{rd} clock signal CK3 corresponds to a high voltage level, and the current-stage stage signal ST(n) corresponds to a high voltage level such that the first NAND circuit outputs a high voltage level to make the first buffer output circuit output the first scan signal G(n) having a low voltage level such that the second buffer output circuit outputs the second scan signal G(n)′ having a high voltage level.

In the second pull-down stage t4, the 3^{rd} clock signal CK3 corresponds to a low voltage level and the current-stage stage signal ST(n) corresponds to a high voltage level such that the second NAND circuit outputs a high voltage level to make the second buffer output circuit output the second scan signal G(n)′ having a low voltage level.

In the maintaining stage t5, the previous-stage stage signal ST(n−1) corresponds to a low voltage level such that the second node P corresponds to a low voltage level to turn on the 5^{th} TFT T5 and turn off the 14^{th} TFT T14. The 1^{st} clock signal CK1 corresponds to a high voltage level to turn off the 6^{th} TFT T6 and turn on the 12^{th} TFT T12. The inverted n^{th} clock signal CK(n)′ corresponds to a low voltage level to turn on the 7^{th} TFT T7 and turn off the 11^{th} TFT T11. The 5^{th} TFT T5 and the 7^{th} TFT T7 are turned on such that the first node Q corresponds to a high voltage level to make the current-stage stage signal (ST(n)) a low voltage level and the first NAND gate circuit and the second NAND gate circuit both output a high voltage level and to further make the first buffer output circuit output the first scan signal G(n) having a low voltage level and the second buffer output circuit output the second scan signal G(n)′ having a low voltage level.

Each of the NAND gate circuits of the second latch circuit 300 respectively receives a corresponding clock signal. The corresponding clock signal is a continuous pulse signal.

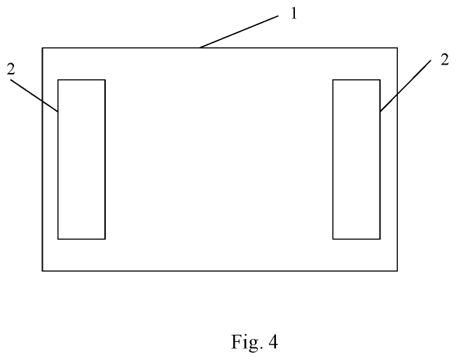

Please refer to FIG. 4. FIG. 4 is a functional block diagram of a display panel according to an embodiment of the present invention. As shown in FIG. 4, a display panel 1 is disclosed. The display panel 1 comprises the above-mentioned GOA circuit 2. The display panel 1 and the GOA circuit 2 have similar structure and benefits. Because related illustration had been fully discussed in the above, further illustration is omitted here.

Above are embodiments of the present invention, which does not limit the scope of the present invention. Any modifications, equivalent replacements or improvements within the spirit and principles of the embodiment described above should be covered by the protected scope of the invention.

What is claimed is:

1. A gate driver on array (GOA) circuit comprising a plurality of cascaded GOA units, each of the GOA unit comprising:
a forward/backward scan module;
a first latch module;
a second latch module, comprising:
a plurality of NAND gate circuits connected in parallel; and
a buffer output module, comprising:
a plurality of buffer output circuits connected in parallel, wherein the plurality of NAND gate circuits and the plurality of buffer output circuits have one-to-one correspondence;
wherein the forward/backward scan module, the first latch module, the second latch module, and the buffer output module are connected in series;
wherein each of the buffer output circuits outputs a corresponding gate scan signal such that the GOA units output a plurality of the gate scan signals.

2. The GOA circuit of claim 1, wherein the forward/backward scan module comprises: a 1^{st} TFT; a 2^{nd} TFT; a 3^{rd} TFT and a 4^{th} TFT; wherein the 1^{st} TFT and the 4^{th} TFT are N-type TFTs and the 2^{nd} TFT and the 3^{rd} TFT are P-type TFTs;
wherein a gate of the 1^{st} TFT and a gate of the 3^{rd} TFT receive a forward scan signal; a gate of the 2^{nd} TFT and a gate of the 4^{th} TFT receive a backward scan signal; a source of the 1^{st} TFT and a source of the 2^{nd} TFT receive a previous-stage stage signal (ST(n−1)) of a previous-stage GOA unit; a source of the 3^{rd} TFT and a source of the 4^{th} TFT receive a next-stage stage signal (ST(n+1)) of a next-stage GOA unit; and drains of the 1^{st} TFT, the 2^{nd} TFT, the 3^{rd} TFT, and the 4^{th} TFT are all electrically connected to a second node.

3. The GOA circuit of claim 2, wherein the first latch module comprises:
a first inverter, comprising a 9^{th} TFT and a 10^{th} TFT; and
a selection inverter, comprising a 5^{th} TFT, a 6^{th} TFT, a 7^{th} TFT, a 8^{th} TFT, a 11^{th} TFT, a 12^{th} TFT, a 13^{th} TFT, and a 14^{th} TFT;
wherein the first inverter and the selection inverter are connected in series;
wherein the 10^{th} TFT, the 11^{th} TFT, the 12^{th} TFT, the 13^{th} TFT, and the 14^{th} TFT are N-type TFTs; and the 5^{th} TFT, the 6^{th} TFT, and the 7^{th} TFT, the 8^{th} TFT, and the 9^{th} TFT are P-type TFTs;
wherein a gate of the 9^{th} TFT and a gate of the 10^{th} TFT receive a n^{th} clock signal (CK(n)); a source of the 9^{th} TFT receives a constant high voltage level, a source of the 10^{th} TFT receives a constant low voltage level; and a drain of the 9^{th} TFT and a drain of the 10^{th} TFT output an inverted n^{th} clock signal (CK(n)′) of the n^{th} clock signal (CK(n));
wherein a gate of the 7^{th} TFT and a gate of the 11^{th} TFT receive the inverted n^{th} clock signal (CK(n)′); a gate of the 5^{th} TFT is electrically connected to the second node; a gate of the 6^{th} TFT and a gate of the 12^{th} TFT receive the n^{th} clock signal (CK(n)); a gate of the 8^{th} TFT and a gate of the 13^{th} TFT receive a current-stage stage signal (ST(n)) of a current-stage GOA unit; a gate of 14^{th} TFT is electrically connected to the second node; drains of the 5^{th} TFT, the 6^{th} TFT, the 7^{th} TFT and the 8^{th} TFT are electrically connected to each other; drains of the 11^{th} TFT, the 12^{th} TFT, the 13^{th} TFT, and the 14^{th} TFT are electrically connected to each other; drains of the 7^{th} TFT, the 8^{th} TFT, the 12^{th} TFT, and the 14^{th} TFT are electrically connected to a first node.

4. The GOA circuit of claim 3, further comprising:
a reset module, comprising:
a 15^{th} TFT, having a gate receiving a reset signal (Reset), a source receiving the constant high voltage level, and a drain electrically connected to the first node.

5. The GOA circuit of claim 4, wherein the second latch module further comprises a plurality of second inverters respectively connected in series with the NAND gate circuits;
wherein the second inverter comprises a 16^{th} TFT and a 17^{th} TFT, the 16^{th} TFT is a P-type TFT and the 17^{th} TFT is an N-type TFT;
wherein a source of the 16^{th} TFT receives the constant high voltage level, a gate of the 16^{th} TFT and a gate of the 17^{th} TFT are electrically connected to the first node; a source of the 17^{th} TFT receives the constant low voltage level; drains of the 16^{th} TFT and the 17^{th} TFT output the current-stage stage signal (ST(n)).

6. The GOA circuit of claim 5, wherein if one stage of the GOA units outputs a first scan signal (G(n)) and a second scan signal (G(n)′), the second latch module comprises a first NAND gate circuit and a second NAND gate circuit; the buffer output module comprises a first buffer output circuit and a second buffer output circuit;
wherein the first NAND gate circuit comprises 19^{th} TFT, a 20^{th} TFT, a 21^{st} TFT, and a 22^{nd} TFT; and the 19^{th} TFT and the 20^{th} TFT are P-type TFTs; and the 21^{st} TFT and the 22^{nd} TFT are P-type TFTs;
wherein the second NAND gate circuit comprises a 19^{th} symmetric TFT, a 20^{th} symmetric TFT, and a 21^{st} symmetric TFT; the 19^{th} symmetric TFT and the 20^{th} symmetric TFT are P-type TFTs; and the 21^{st} symmetric TFT is an N-type TFT;
wherein gates of the 19^{th} TFT, the 22^{nd} TFT, and the 19^{th} symmetric TFT receive the current-stage stage signal (ST(n)), gates of the 20^{th} TFT and the 21^{st} TFT receive a (n+1)th clock signal (CK(n+1)); sources of the 19^{th} TFT and the 20^{th} TFT receive the constant high voltage level; drains of the 19^{th} TFT and the 20^{th} TFT are electrically connected to a source of the 21^{st} TFT; a drain of the 21^{st} TFT is electrically connected to drains of the 22^{nd} TFT and the 21^{st} symmetric TFT; sources of the 19^{th} TFT, the 20^{th} symmetric TFT and the 22^{nd} TFT receive the constant low voltage level; drains of the 19^{th} symmetric TFT and the 20^{th} symmetric TFT are electrically connected to a source of the 21^{st} symmetric TFT; and gates of the 20^{th} symmetric TFT and the 21^{st} symmetric TFT receive a (n+2)th clock signal (CK(n+2));
wherein the first buffer output circuit and the second buffer output circuit respectively comprises an odd number of third inverters connected in series, the first buffer output circuit outputs the first scan signal (G(n)) and the second buffer output circuit outputs the second scan signal (G(n)′).

7. The GOA circuit of claim 6, wherein the GOA circuit has four clock signals: a 1^{st} clock signal (CK1), a 2^{nd} clock signal (CK2), a 3^{rd} clock signal (CK3) and a 4^{th} clock signal (CK4); wherein when the n^{th} clock signal (CK(n)) is the 3^{rd} clock signal (CK3), the (n+1)th clock signal (CK(n+1)) is the 4^{th} clock signal (CK4) and the (n+2)th clock signal (CK(n+2)) is the 1^{st} clock signal (CK1); and when the n^{th} clock signal (CK(n)) is the 4^{th} clock signal (CK4), the (n+1)th clock signal (CK(n+1)) is the 1^{st} clock signal (CK1) and the (n+2)th clock signal (CK(n+2)) is the 2^{nd} clock signal (CK2).

8. The GOA circuit of claim 7, wherein the n^{th} clock signal (CK(n)) is the 1^{st} clock signal (CK1), the operation of the GOA circuit comprises an initial stage (t0), an input stage (t1), a first output stage (t2), a first pull-down and a second output stage (t3), a second pull-down stage (t4), and a maintaining stage (t5);
wherein in the initial stage (t0), the reset signal (Reset) corresponds to a low voltage level such that the first node corresponds to a low voltage level and the current-stage stage signal (ST(n)) corresponds to a high voltage level to make the buffer output module outputs a low voltage level;
wherein in the input stage (t1), the previous-stage stage signal (ST(n−1)) corresponds to a high voltage level such that the second node corresponds to a high voltage level and the 5^{th} TFT is turned off and the 14^{th} TFT is turned on; the 1^{st} clock signal (CK1) corresponds to a high voltage level such that the 6^{th} TFT is turned off and the 12^{th} TFT is turned on; the inverted n^{th} clock signal (CK(n)′) corresponds to a low voltage level such that the 11^{th} TFT is turned off; the 12^{th} TFT and the 14^{th} TFT are turned on such that the first node corresponds to a low voltage level to make the current-stage stage signal (ST(n)) a high voltage level;
wherein in the first output stage (t2), the 2^{nd} clock signal (CK2) corresponds to a high voltage level and the current-stage stage signal (ST(n)) corresponds to a high voltage level such that the first NAND gate circuit outputs a low voltage level to make the first buffer output circuit outputs the first scan signal (G(n)) having a high voltage level;
wherein in the first pull-down and a second output stage (t3), the 2^{nd} clock signal (CK2) corresponds to a low voltage level, the 3^{rd} clock signal (CK3) corresponds to a high voltage level, and the current-stage stage signal (ST(n)) corresponds to a high voltage level such that the first NAND circuit outputs a high voltage level to make the first buffer output circuit output the first scan signal (G(n)) having a low voltage level such that the second buffer output circuit outputs the second scan signal (G(n)′) having a high voltage level;
wherein in the second pull-down stage (t4), the 3^{rd} clock signal (CK3) corresponds to a low voltage level and the current-stage stage signal (ST(n)) corresponds to a high voltage level such that the second NAND circuit outputs a high voltage level to make the second buffer output circuit output the second scan signal (G(n)′) having a low voltage level; and
wherein in the maintaining stage (t5), the previous-stage stage signal (ST(n−1)) corresponds to a low voltage level such that the second node corresponds to a low voltage level to turn on the 5^{th} TFT and turn off the 14^{th} TFT; the 1^{st} clock signal (CK1) corresponds to a high voltage level to turn off the 6^{th} TFT and turn on the 12^{th} TFT; the inverted n^{th} clock signal (CK(n)′) corresponds to a low voltage level to turn on the 7^{th} TFT and turn off the 11^{th} TFT; the 5^{th} TFT and the 7^{th} TFT are turned on such that the first node corresponds to a high voltage level to make the current-stage stage signal (ST(n)) a low voltage level and the first NAND gate circuit and the second NAND gate circuit both output a high voltage level and to further make the first buffer output circuit output the first scan signal (G(n)) having a low voltage level and the second buffer output circuit output the second scan signal (G(n)′) having a low voltage level.

9. The GOA circuit of claim 1, wherein each of the NAND gate circuits in the second latch module respectively receives a corresponding clock signal and the corresponding clock signal is a continuous pulse signal.

10. A display panel, comprising a gate driver on array (GOA) circuit comprising a plurality of cascaded GOA units, each of the GOA unit comprising:
a forward/backward scan module;
a first latch module;
a second latch module, comprising:
a plurality of NAND gate circuits connected in parallel; and
a buffer output module, comprising:
a plurality of buffer output circuits connected in parallel, wherein the plurality of NAND gate circuits and the plurality of buffer output circuits have one-to-one correspondence;
wherein the forward/backward scan module, the first latch module, the second latch module, and the buffer output module are connected in series;
wherein each of the buffer output circuits outputs a corresponding gate scan signal such that the GOA units output a plurality of the gate scan signals.

11. The display panel of claim 10, wherein the forward/backward scan module comprises: a 1^{st} TFT; a 2^{nd} TFT; a 3^{rd} TFT and a 4^{th} TFT; wherein the 1^{st} TFT and the 4^{th} TFT are N-type TFTs and the 2^{nd} TFT and the 3^{rd} TFT are P-type TFTs;
wherein a gate of the 1^{st} TFT and a gate of the 3^{rd} TFT receive a forward scan signal; a gate of the 2^{nd} TFT and a gate of the 4^{th} TFT receive a backward scan signal; a source of the 1^{st} TFT and a source of the 2^{nd} TFT receive a previous-stage stage signal (ST(n−1)) of a previous-stage GOA unit; a source of the 3^{rd} TFT and a source of the 4^{th} TFT receive a next-stage stage signal (ST(n+1)) of a next-stage GOA unit; and drains of the 1^{st} TFT, the 2^{nd} TFT, the 3^{rd} TFT, and the 4^{th} TFT are all electrically connected to a second node.

12. The display panel of claim 11, wherein the first latch module comprises:
a first inverter, comprising a 9^{th} TFT and a 10^{th} TFT; and
a selection inverter, comprising a 5^{th} TFT, a 6^{th} TFT, a 7^{th} TFT, a 8^{th} TFT, a 11^{th} TFT, a 12^{th} TFT, a 13^{th} TFT, and a 14^{th} TFT;
wherein the first inverter and the selection inverter are connected in series;
wherein the 10^{th} TFT, the 11^{th} TFT, the 12^{th} TFT, the 13^{th} TFT, and the 14^{th} TFT are N-type TFTs; and the 5^{th} TFT, the 6^{th} TFT, and the 7^{th} TFT, the 8^{th} TFT, and the 9^{th} TFT are P-type TFTs;
wherein a gate of the 9^{th} TFT and a gate of the 10^{th} TFT receive a n^{th} clock signal (CK(n)); a source of the 9^{th} TFT receives a constant high voltage level, a source of the 10^{th} TFT receives a constant low voltage level; and a drain of the 9^{th} TFT and a drain of the 10^{th} TFT output an inverted n^{th} clock signal (CK(n)′) of the n^{th} clock signal (CK(n));
wherein a gate of the 7^{th} TFT and a gate of the 11^{th} TFT receive the inverted n^{th} clock signal (CK(n)′); a gate of the 5^{th} TFT is electrically connected to the second node; a gate of the 6^{th} TFT and a gate of the 12^{th} TFT receive the n^{th} clock signal (CK(n)); a gate of the 8^{th} TFT and a gate of the 13^{th} TFT receive a current-stage stage signal (ST(n)) of a current-stage GOA unit; a gate of 14^{th} TFT is electrically connected to the second node; drains of the 5^{th} TFT, the 6^{th} TFT, the 7^{th} TFT and the 8^{th} TFT are electrically connected to each other; drains of the 11^{th} TFT, the 12^{th} TFT, the 13^{th} TFT, and the 14^{th} TFT are electrically connected to each other; drains of the 7^{th} TFT, the 8^{th} TFT, the 12^{th} TFT, and the 14^{th} TFT are electrically connected to a first node.

13. The display panel of claim 12, wherein the GOA circuit further comprises:
a reset module, comprising:
a 15^{th} TFT, having a gate receiving a reset signal (Reset), a source receiving the constant high voltage level, and a drain electrically connected to the first node.

14. The display panel of claim 13, wherein the second latch module further comprises a plurality of second inverters respectively connected in series with the NAND gate circuits;
wherein the second inverter comprises a 16^{th} TFT and a 17^{th} TFT, the 16^{th} TFT is a P-type TFT and the 17^{th} TFT is an N-type TFT;
wherein a source of the 16^{th} TFT receives the constant high voltage level, a gate of the 16^{th} TFT and a gate of the 17^{th} TFT are electrically connected to the first node; a source of the 17^{th} TFT receives the constant low voltage level; drains of the 16^{th} TFT and the 17^{th} TFT output the current-stage stage signal (ST(n)).

15. The display panel of claim 14, wherein if one stage of the GOA units outputs a first scan signal (G(n)) and a second scan signal (G(n)′), the second latch module comprises a first NAND gate circuit and a second NAND gate circuit; the buffer output module comprises a first buffer output circuit and a second buffer output circuit;
wherein the first NAND gate circuit comprises 19^{th} TFT, a 20^{th} TFT, a 21^{st} TFT, and a 22^{nd} TFT; and the 19^{th} TFT and the 20^{th} TFT are P-type TFTs; and the 21^{st} TFT and the 22^{nd} TFT are P-type TFTs;
wherein the second NAND gate circuit comprises a 19^{th} symmetric TFT, a 20^{th} symmetric TFT, and a 21^{st} symmetric TFT; the 19^{th} symmetric TFT and the 20^{th} symmetric TFT are P-type TFTs; and the 21^{st} symmetric TFT is an N-type TFT;
wherein gates of the 19^{th} TFT, the 22^{nd} TFT, and the 19^{th} symmetric TFT receive the current-stage stage signal (ST(n)), gates of the 20^{th} TFT and the 21^{st} TFT receive a (n+1)th clock signal (CK(n+1)); sources of the 19^{th} TFT and the 20^{th} TFT receive the constant high voltage level; drains of the 19^{th} TFT and the 20^{th} TFT are electrically connected to a source of the 21^{st} TFT; a drain of the 21^{st} TFT is electrically connected to drains of the 22^{nd} TFT and the 21^{st} symmetric TFT; sources of the 19^{th} TFT, the 20^{th} symmetric TFT and the 22^{nd} TFT receive the constant low voltage level; drains of the 19^{th} symmetric TFT and the 20^{th} symmetric TFT are electrically connected to a source of the 21^{st} symmetric TFT; and gates of the 20^{th} symmetric TFT and the 21^{st} symmetric TFT receive a (n+2)th clock signal (CK(n+2));
wherein the first buffer output circuit and the second buffer output circuit respectively comprises an odd number of third inverters connected in series, the first buffer output circuit outputs the first scan signal (G(n)) and the second buffer output circuit outputs the second scan signal (G(n)′).

16. The display panel of claim 15, wherein the GOA circuit has four clock signals: a 1^{st} clock signal (CK1), a 2^{nd} clock signal (CK2), a 3^{rd} clock signal (CK3) and a 4^{th} clock signal (CK4); wherein when the n^{th} clock signal (CK(n)) is the 3rd clock signal (CK3), the (n+1)th clock signal (CK(n+1)) is the 4^{th} clock signal (CK4) and the (n+2)th clock signal (CK(n+2)) is the 1^{st} clock signal (CK1); and when the n^{th} clock signal (CK(n)) is the 4^{th} clock signal (CK4), the (n+1)th clock signal (CK(n+1)) is the 1^{st} clock signal (CK1) and the (n+2)th clock signal (CK(n+2)) is the 2^{nd} clock signal (CK2).

17. The display panel of claim 16, wherein the n^{th} clock signal (CK(n)) is the 1^{st} clock signal (CK1), the operation of the GOA circuit comprises an initial stage (t0), an input stage (t1), a first output stage (t2), a first pull-down and a second output stage (t3), a second pull-down stage (t4), and a maintaining stage (t5);
wherein in the initial stage (t0), the reset signal (Reset) corresponds to a low voltage level such that the first node corresponds to a low voltage level and the current-stage stage signal (ST(n)) corresponds to a high voltage level to make the buffer output module outputs a low voltage level;
wherein in the input stage (t1), the previous-stage stage signal (ST(n−1)) corresponds to a high voltage level such that the second node corresponds to a high voltage level and the 5^{th} TFT is turned off and the 14^{th} TFT is turned on; the 1^{st} clock signal (CK1) corresponds to a high voltage level such that the 6^{th} TFT is turned off and the 12^{th} TFT is turned on; the inverted n^{th} clock signal (CK(n)′) corresponds to a low voltage level such that the 11^{th} TFT is turned off; the 12^{th} TFT and the 14^{th} TFT are turned on such that the first node corresponds to a low voltage level to make the current-stage stage signal (ST(n)) a high voltage level;
wherein in the first output stage (t2), the 2^{nd} clock signal (CK2) corresponds to a high voltage level and the current-stage stage signal (ST(n)) corresponds to a high voltage level such that the first NAND gate circuit outputs a low voltage level to make the first buffer output circuit outputs the first scan signal (G(n)) having a high voltage level;
wherein in the first pull-down and a second output stage (t3), the 2^{nd} clock signal (CK2) corresponds to a low voltage level, the 3^{rd} clock signal (CK3) corresponds to a high voltage level, and the current-stage stage signal (ST(n)) corresponds to a high voltage level such that the first NAND circuit outputs a high voltage level to make the first buffer output circuit output the first scan signal (G(n)) having a low voltage level such that the second buffer output circuit outputs the second scan signal (G(n)′) having a high voltage level;
wherein in the second pull-down stage (t4), the 3^{rd} clock signal (CK3) corresponds to a low voltage level and the current-stage stage signal (ST(n)) corresponds to a high voltage level such that the second NAND circuit outputs a high voltage level to make the second buffer output circuit output the second scan signal (G(n)′) having a low voltage level; and
wherein in the maintaining stage (t5), the previous-stage stage signal (ST(n−1)) corresponds to a low voltage level such that the second node corresponds to a low voltage level to turn on the 5^{th} TFT and turn off the 14^{th} TFT; the 1^{st} clock signal (CK1) corresponds to a high voltage level to turn off the 6^{th} TFT and turn on the 12^{th} TFT; the inverted n^{th} clock signal (CK(n)′) corresponds to a low voltage level to turn on the 7^{th} TFT and turn off the 11^{th} TFT; the 5^{th} TFT and the 7^{th} TFT are turned on such that the first node corresponds to a high voltage level to make the current-stage stage signal (ST(n)) a low voltage level and the first NAND gate circuit and the second NAND gate circuit both output a high voltage level and to further make the first buffer output circuit output the first scan signal (G(n)) having a low voltage level and the second buffer output circuit output the second scan signal (G(n)′) having a low voltage level.

18. The display panel of claim 10, wherein each of the NAND gate circuits in the second latch module respectively receives a corresponding clock signal and the corresponding clock signal is a continuous pulse signal.
